(19) United States
(12) Patent Application Publication
(10) Pub. No.: US 2017/0047277 A1
(43) Pub. Date: Feb. 16, 2017

(54) SEMICONDUCTOR STRUCTURE

(71) Applicant: Powertech Technology Inc., Hsinchu County (TW)

(72) Inventors: Yuan-Fu Lan, Hsinchu County (TW); Hsien-Wen Hsu, Hsinchu County (TW)

(21) Appl. No.: 15/096,293

(22) Filed: Apr. 12, 2016

(30) Foreign Application Priority Data
Aug. 14, 2015 (TW) 104126612

(51) Int. Cl. H01L 23/498; H05K 3/26; H05K 1/02; H05K 3/00

(52) U.S. Cl. CPC H01L 23/49838; H01L 23/49866; H05K 3/0017; H05K 3/26; H05K 1/0271

(57) ABSTRACT

Provided is a semiconductor structure including a first die and a second die. The first die has a first conductive structure embedded in a dielectric layer. The second die has a second conductive structure embedded in the dielectric layer. A first interface is provided between the first conductive structure and the dielectric layer. A second interface is provided between the second conductive structure and the dielectric layer. A shape of the dielectric layer between the first interface and the second interface is a non-linear shape.

### CROSS-REFERENCE TO RELATED APPLICATION

This application claims the priority benefit of Taiwan application serial no. 104126612, filed on Aug. 14, 2015. The entirety of the above-mentioned patent application is hereby incorporated by reference herein and made a part of this specification.

### BACKGROUND OF THE INVENTION

1. Field of the Invention

The invention relates to an integrated circuit, and particularly relates to a semiconductor structure.

2. Description of Related Art

In recent years, with the rapid progress of electronic technologies, and the prosperous development of high-tech electronic industries, more user-friendly electronic products with better functions continuously emerge and evolve toward a light, thin, short and small trend. Therefore, the concept of the molded interconnect device (MID) is developed.

The technique of molded interconnect device is different from the traditional planar printed circuit board. The technique of molded interconnect device integrates the mechanical and electronic functions into a single plastic component to form a three-dimensional circuit structure on the surface of the three-dimensional structure, thereby allowing the electronic products to become more miniaturized. However, in the process of assembling, the connection between the electronic material and the plastic material of the molded interconnect device may break easily, which makes the product less reliable. Therefore, solving the breakage between the electronic material and the plastic material of the molded interconnect device under a certain external force becomes an important issue.

### SUMMARY OF THE INVENTION

The invention provides a semiconductor structure capable of solving the breakage between an electronic material and a plastic material of a molded interconnect device, thereby improving the reliability of the product.

The invention provides a semiconductor structure including a first die and a second die. The first die has a first conductive structure embedded in a dielectric layer. The second die has a second conductive structure embedded in the dielectric layer. A first interface is provided between the first conductive structure and the dielectric layer. A second interface is provided between the second conductive structure and the dielectric layer. A shape of the dielectric layer between the first interface and the second interface is a non-linear shape.

In an embodiment of the invention, the shape of the dielectric layer between the first interface and the second interface includes a rectangular zigzag shape, a V-shaped zigzag shape, a semicircular zigzag shape, a wavy shape or a combination thereof.

In an embodiment of the invention, each of the first conductive structure and the second conductive structure includes a conductive line layer, a conductive post or a combination thereof.

In an embodiment of the invention, a material of the first conductive structure and a material of the second conductive structure include a metal material. The metal material includes copper, aluminium, gold, silver, nickel, palladium or a combination thereof.

In an embodiment of the invention, a material of the dielectric layer includes a plastic material. The plastic material includes Ajinomoto build-up film (ABF) resin, polymer material, silica filler or epoxy.

The invention provides a semiconductor structure including a dielectric layer and a conductive structure. The conductive structure is embedded in the dielectric layer, and a top surface of the conductive structure is exposed. The conductive structure has a first portion and a second portion located on the first portion. A width of the first portion is different from a width of the second portion.

In an embodiment of the invention, the width of the first portion is smaller than the width of the second portion.

In an embodiment of the invention, sidewalls of the first portion and the second portion are in a stepped shape.

In an embodiment of the invention, an interface is provided between the conductive structure and the dielectric layer. A shape of the interface includes a rectangular zigzag shape, a V-shaped zigzag shape, a semicircular zigzag shape, a wavy shape or a combination thereof.

In an embodiment of the invention, a material of the conductive structure includes a metal material. The metal material includes copper, aluminium, gold, silver, nickel, palladium or a combination thereof.

Base on the above, by changing the shape of the first interface provided between the first conductive structure and the dielectric layer as well as the shape of the second interface provided between the second conductive structure and the dielectric layer, the invention reduces the breakage among the first conductive structure, the second conductive structure and the dielectric layer, and thereby improve the reliability of the product. In addition, the conductive structures of the invention have the first portion and the second portion of different widths for increasing a contact area among the first conductive structure, the second conductive structure and the dielectric layer to reduce the breakage among the first conductive structure, the second conductive structure and the dielectric layer, and thereby improve the reliability of the product.

In order to make the aforementioned features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a semiconductor structure of an embodiment of the invention.

FIG. 2A to FIG. 2D are schematic top views respectively illustrating portions of FIG. 1.

FIG. 3 to FIG. 4 are respectively schematic cross-sectional views taken along line A-A of FIG. 2A.

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

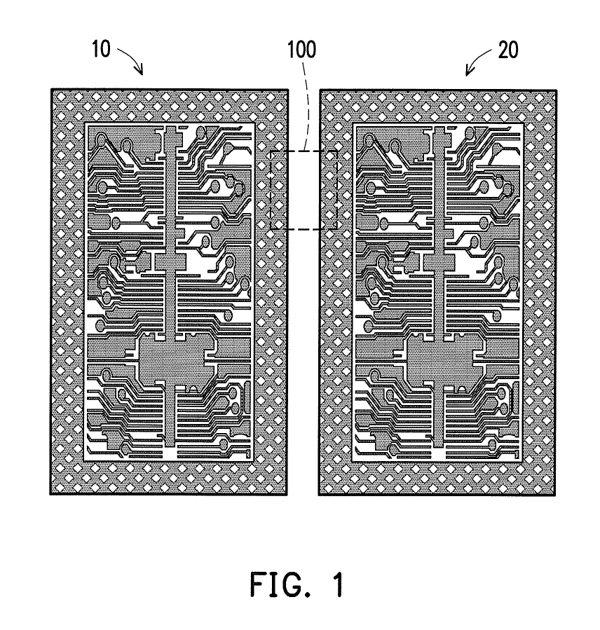

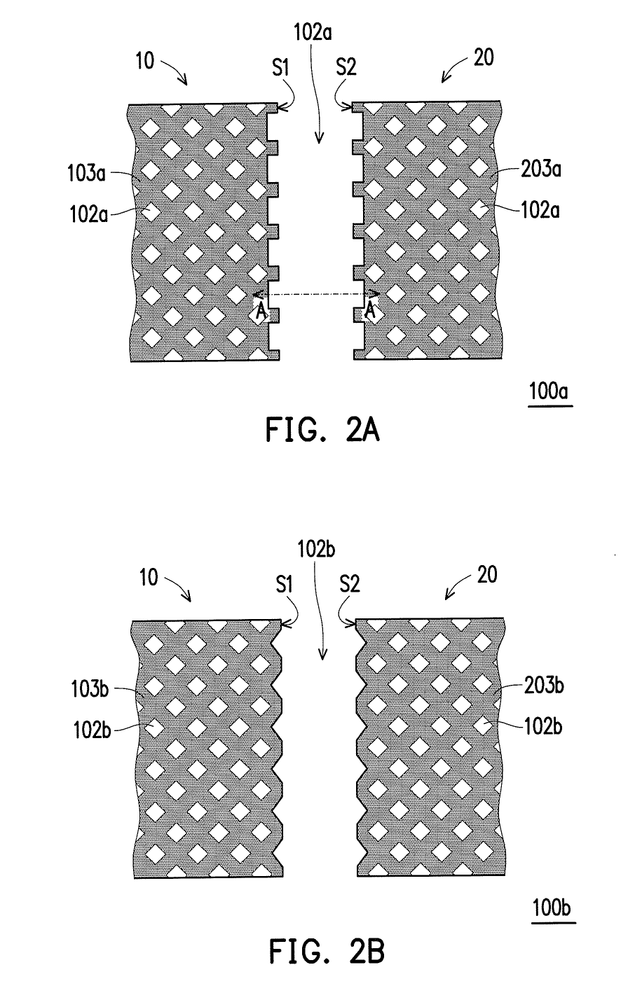

In embodiments below, same or similar devices, components and layers are represented by similar reference numbers. For example, a portion 100 of FIG. 1, a portion 100a of FIG. 2A, a portion 100b of FIG. 2B, a portion 100c of FIG. 2C and a portion 100d of FIG. 2D are same or similar components, and details thereof are not repeated.

FIG. 1 is a schematic top view illustrating a semiconductor structure of an embodiment of the invention. FIG. 2A to FIG. 2D are schematic top views respectively illustrating portions of FIG. 1.

Referring to FIG. 1, the semiconductor structure of the embodiment includes a first die 10 and a second die 20. There is a distance between the first die 10 and the second die 20, so as to separate the two dies. In an embodiment, the first die 10 and the second die 20 may be dies having the same function or different functions, for example, but the invention is not limited thereto.

Specifically, using FIG. 2A as example, the first die 10 has a first conductive structure 103a embedded in a dielectric layer 102a. The second die 20 has a second conductive structure 203a embedded in the dielectric layer 102a. In an embodiment, a material of the first conductive structure 103a and a material of the second conductive structure 203a include a metal material. The metal material includes copper, aluminium, gold, silver, nickel, palladium or a combination thereof, for example. In an embodiment, a process of forming the first conductive structure 103a and the second conductive structure 203a includes performing a plating process, for example, but the invention is not limited thereto.

A material of the dielectric layer 102a includes a plastic material. The plastic material, for example, includes Ajinomoto build-up film (ABF) resin, polymer material, silica filler or epoxy. In an embodiment, the material of the dielectric layer 102a includes ABF, benzocyclo-buthene (BCB), liquid crystal polymer (LCP), poly-imide, polyphenylene ether (PPE), FR4, FR5, aramide (or aramid), glass fiber mixed with epoxy or a combination thereof, for example. A process of forming the dielectric layer 102a includes first forming a dielectric material layer (not illustrated) to cover surfaces of the first conductive structure 103a and the second conductive structure 203a, for example. In an embodiment, a process of forming the dielectric material layer includes performing a molding process, for example. Then, a portion of the dielectric material layer is removed to expose the surfaces of the first conductive structure 103a and the second conductive structure 203a. In an embodiment, the portion of the dielectric material layer may be removed by performing an etching back process or a chemical mechanical polishing (CMP) process.

It should be noted that a first interface S1 is provided between the first conductive structure 103a and the dielectric layer 102a. A second interface S2 is provided between the second conductive structure 203a and the dielectric layer 102a. Since the shape of the dielectric layer 102a between the first interface S1 and the second interface S2 is a non-linear shape, a contact area among the first conductive structure 103a, the second conductive structure 203a and the dielectric layer 102a may be increased in this embodiment, so as to solve the easy breakage between the first interface S1 and the second interface S2, and thereby improve the reliability of the product.

FIG. 2A to FIG. 2D illustrate various embodiments of the portion 100 between the first die 10 and the second die 20 of FIG. 1. Referring FIG. 2A to FIG. 2D, in the embodiments, a patterning process may be performed to respectively form the first conductive structures 103a to 103d and the second conductive structures 203a to 203d, so as to change the shapes of the dielectric layers 102a to 102d between the first interface S1 and the second interface S2. In an embodiment, the shapes of dielectric layers 102a to 102d between the first interface S1 and the second interface S2 may include a rectangular zigzag shape (as showed in FIG. 2A), a V-shaped zigzag shape (as showed in FIG. 2B), a semicircular zigzag shape (as showed in FIG. 2C), a wavy shape (as showed in FIG. 2D) or a combination thereof, for example. However, the invention is not limited thereto. In other embodiments, as long as the shape of the dielectric layer between the first interface S1 and the second interface S2 is a non-linear shape, the shape may be designed based on a desired circuit layout. In addition, although the zigzag shapes or the wavy shapes illustrated in FIG. 2A to FIG. 2D are symmetric patterns, the invention is not limited thereto. The zigzag shapes or the wavy shapes may also be asymmetric shapes.

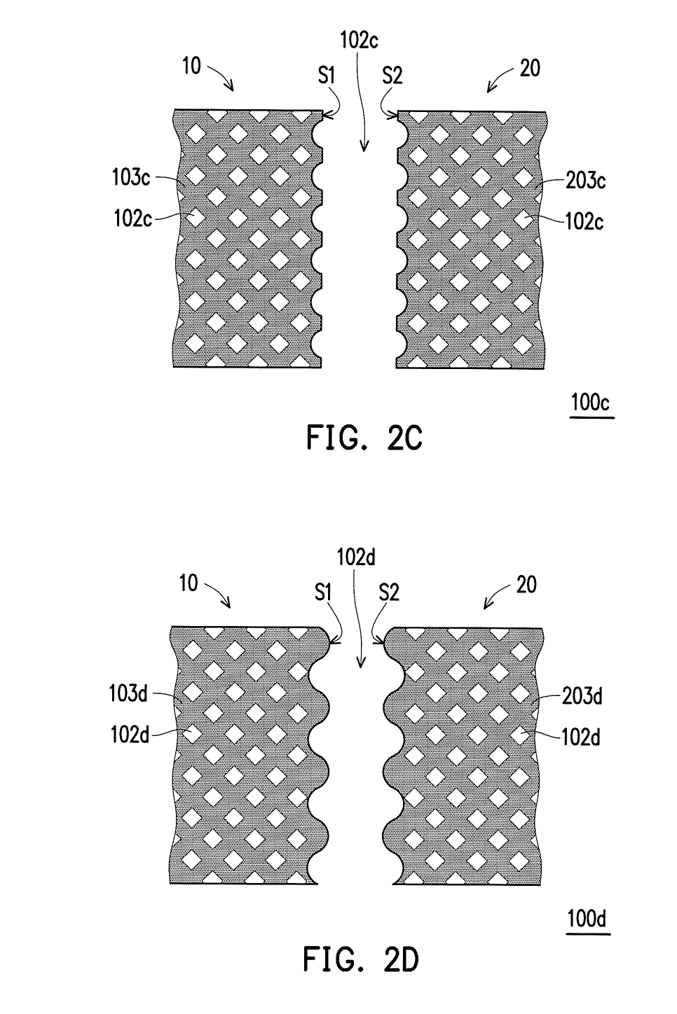

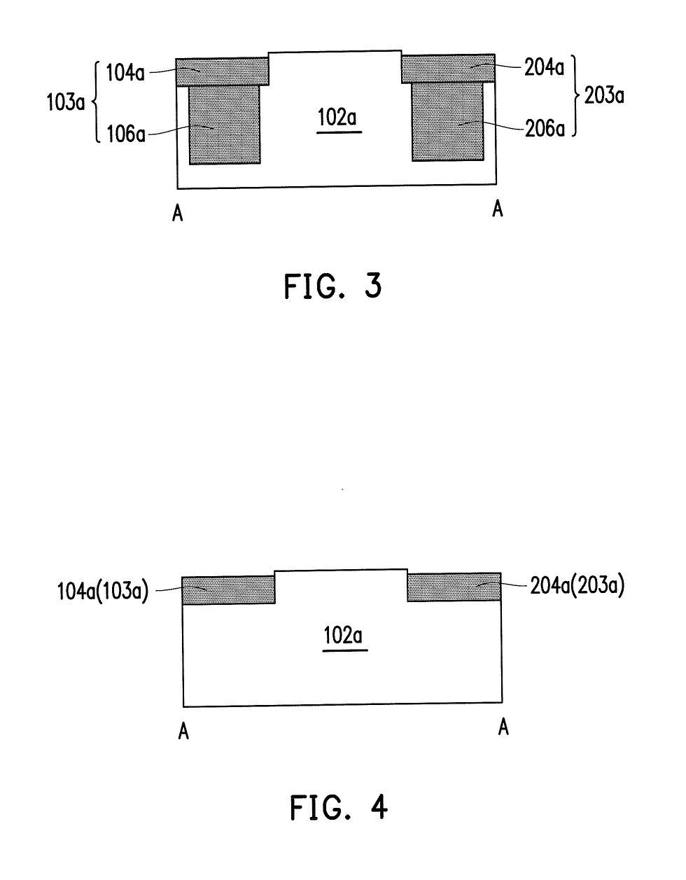

FIG. 3 to FIG. 4 are respectively schematic cross-sectional views taken along line A-A of FIG. 2A.

On the other hand, referring to FIG. 3, the semiconductor structure of the embodiment includes the first conductive structure 103a embedded in the dielectric layer 102a, and a top surface of the first conductive structure 103a is exposed. The second conductive structure 203a is embedded in the dielectric layer 102a, and a top surface of the second conductive structure 203a is exposed. Although the top surfaces of the first conductive structure 103a and the second conductive structure 203a illustrated in FIG. 3 are lower than a top surface of the dielectric layer 102a, the invention is not limited thereto. In other embodiments, the top surfaces of the first conductive structure 103a and the second conductive structure 203a may also be coplanar with the top surface of the dielectric layer 102a.

In detail, the first conductive structure 103a has a first portion 106a (such as a conductive post) and a second portion 104a (such as a conductive line layer) located on the first portion 106a. Widths of the first portion 106a and the second portion 104a are different. In an embodiment, the width of the first portion 106a is smaller than the width of the second portion 104a. In an embodiment, a shape of sidewalls of the first portion 106a and the second portion 104a includes a stepped shape, for example. And the sidewalls may also increase the contact area among the first conductive structure 103a, the second conductive structure 203a and the dielectric layer 102a, so as to solve the easy breakage between the first interface S1 and the second interface S2, and thereby improve the reliability of the product.

Similarly, the second conductive structure 203a has a first portion 206a (such as the conductive post) and a second portion 204a (such as the conductive line layer) located on the first portion 206a. Widths of the first portion 206a and the second portion 204a are different. In an embodiment, the width of the first portion 206a is smaller than the width of the second portion 204a. In an embodiment, a shape of sidewalls of the first portion 206a and the second portion 204a includes a stepped shape, for example.

In addition, referring to FIG. 4, FIG. 4 is substantially similar to the schematic cross-sectional view of FIG. 3. Differences between FIG. 4 and FIG. 3 are: the first conductive structure 103a and the second conductive structure 203a shown in FIG. 4 only have the second portions 104a and 204a (such as conductive line layers), and have no first portions 106a and 206a (such as conductive posts).

It should be noted that although FIG. 3 and FIG. 4 only illustrate one dielectric layer 102a and one conductive structure 103a, 203a, the invention is not limited thereto. In other embodiments, the semiconductor structure may also include a plurality of dielectric layers and a plurality of conductive structures.

In sum, by changing the shape of the first interface between the first conductive structure and the dielectric layer as well as the shape of the second interface between the second conductive structure and the dielectric layer, the invention reduces the breakage among the first conductive structure, the second conductive structure and the dielectric layer, and thereby improves the reliability of the product. In addition, the conductive structures of the invention have the first portions and the second portions of different widths for increasing the contact area among the first conductive structure, the second conductive structure and the dielectric layer to reduce the breakage among the first conductive structure, the second conductive structure and the dielectric layer, and thereby improve the reliability of the product.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A semiconductor structure, comprising:
a first die having a first conductive structure embedded in a dielectric layer; and
a second die having a second conductive structure embedded in the dielectric layer, wherein a first interface is provided between the first conductive structure and the dielectric layer, and a second interface is provided between the second conductive structure and the dielectric layer, a shape of the dielectric layer between the first interface and the second interface being a non-linear shape.

2. The semiconductor structure as recited in claim 1, wherein the shape of the dielectric layer between the first interface and the second interface comprises a rectangular zigzag shape, a V-shaped zigzag shape, a semicircular zigzag shape, a wavy shape or a combination thereof.

3. The semiconductor structure as recited in claim 1, wherein each of the first conductive structure and the second conductive structure comprises a conductive line layer, a conductive post or a combination thereof.

4. The semiconductor structure as recited in claim 1, wherein a material of the first conductive structure and a material of the second conductive structure comprise a metal material, and the metal material comprises copper, aluminium, gold, silver, nickel, palladium or a combination thereof.

5. The semiconductor structure as recited in claim 1, wherein a material of the dielectric layer comprises a plastic material, and the plastic material comprises Ajinomoto build-up film resin, polymer material, silica filler or epoxy.

6. A semiconductor structure, comprising:
a dielectric layer; and
a conductive structure embedded in the dielectric layer, wherein a top surface of the conductive structure is exposed, the conductive structure has a first portion and a second portion located on the first portion, and a width of the first portion is different from a width of the second portion.

7. The semiconductor structure as recited in claim 6, wherein the width of the first portion is smaller than the width of the second portion.

8. The semiconductor structure as recited in claim 6, sidewalls of the first portion and the second portion are in a stepped shape.

9. The semiconductor structure as recited in claim 6, wherein an interface is provided between the conductive structure and the dielectric layer, and a shape of the interface comprises a rectangular zigzag shape, a V-shaped zigzag shape, a semicircular zigzag shape, a wavy shape or a combination thereof.

10. The semiconductor structure as recited in claim 6, wherein a material of the conductive structure comprises a metal material, and the metal material comprises copper, aluminium, gold, silver, nickel, palladium or a combination thereof.
